(19) United States
(12) Patent Application Publication
(10) Pub. No.: US 2012/0024589 A1
(43) Pub. Date: Feb. 2, 2012

(54) SHIELDING CASE

(75) Inventor: Shern-Yun Shian, Taipei City (TW)

(73) Assignee: PRIMECON TECHNOLOGY LTD., Taipei (TW)

(21) Appl. No.: 13/037,991

(22) Filed: Mar. 1, 2011

(30) Foreign Application Priority Data
Jul. 30, 2010 (TW) 099214635

(51) Int. Cl. H05K 9/00

(52) U.S. Cl. 174/382

(57) ABSTRACT

A shielding case includes a frame, a cover, and a connector. The frame is provided on two lateral top edges with two guide rails, which are provided at respective one end with a limiting section. The frame is also provided on bottom edges with a plurality of spaced pins, and at one of two opposite end faces with a through hole. The cover is provided at two lateral sides with two slide channels for slidably receiving the guide rails therein, and the two slide channels are provided at respective one end with a retaining hole for releasably engaging with the limiting sections on the guide rails, so that the cover is removably connected to the frame to close an open top thereof. The connector is detachably mounted to the through hole from an outer side of the frame. Thus, the shielding case can be easily assembled and disassembled.

### CROSS-REFERENCE TO RELATED APPLICATION

This non-provisional application claims priority under 35 U.S.C. §119(a) on Patent Application No(s). 099214635 filed in Taiwan, R.O.C. on Jul. 30, 2010, the entire contents of which are hereby incorporated by reference.

### FIELD OF THE INVENTION

The present invention relates to a shielding case, and more particularly to a shielding case that includes a frame and a cover being removably connected to each other via sliding engagement of slide channels with guide rails and releasable engagement of retaining holes with limiting sections, and can therefore be easily assembled and disassembled.

### BACKGROUND OF THE INVENTION

A conventional shielding case 4, as shown in FIG. 1, is generally assembled from a frame 41, a top cover 42 and a connector 43. The frame 41 is provided on one end face with a through hole 44, via which the connector 43 is partially extended into the frame 41. A plurality of bending tabs 441 is formed along the through hole 44 through punching for connecting with the connector 43. Downward extended flanges 421 are formed along outer edges of the top cover 42. When the top cover 42 has been closed onto an open top of the frame 41, the flanges 421 of the top cover 42 are welded to the frame 41 to complete the shielding case 4 for a communication device.

According to the conventional shielding case 4, the top cover 42 is immovably connected to the frame 41 by welding the flanges 421 to the frame 41, and the connector 43 is held to the through hole 44 by punching the through hole to form the bending tabs 441 for connecting to the connector 43. With these arrangements, the assembling of the shielding case 4 involves complicated procedures. Further, once the top cover 42 and the connector 43 are connected to the frame 41 to complete the shielding case 4, the shielding case 4 forms a fixed structure and could not be easily disassembled to match actual need in practical application of the shielding case 4.

It is therefore tried by the inventor to develop an improved shielding case that can be easily assembled and disassembled to overcome the drawbacks in the conventional shielding case.

### SUMMARY OF THE INVENTION

A primary object of the present invention is to provide a shielding case, which can be easily assembled and disassembled by including slide channels and guide rails as well as retaining holes and limiting sections to removably connect a cover to a frame of the shielding case.

To achieve the above and other objects, the shielding case according to the present invention includes a frame, a cover, and a connector. The frame is provided on two lateral top edges with two guide rails, which are provided at respective one end with a limiting section. The frame is also provided on bottom edges with a plurality of spaced pins, and at one of two opposite end faces with a through hole. The cover is provided at two lateral sides with two slide channels for slidably receiving the guide rails therein, and the two slide channels are provided at respective one end with a retaining hole for releasably engaging with the limiting sections on the guide rails, so that the cover is removably connected to the frame to close an open top thereof. The connector is detachably mounted to the through hole from an outer side of the frame.

In an embodiment of the present invention, the frame includes two opposite side walls and two opposite end walls, which are connected to one another; the slide channels are extended along top edges of the two side walls, and the through hole is provided on one of the two end walls; and the end wall with the through hole is also provided on a top edge with a stop flange, and the cover is provided on one end with a downward bent flange for correspondingly bearing on the stop flange of the frame.

In an embodiment of the present invention, the limiting sections respectively include continuous curved portions.

In an embodiment of the present invention, the frame further includes a plurality of guide tabs and a plurality of holding tabs internally spaced around the through hole; and the connector is provided on an outer surface with a plurality of recesses and a plurality of mounting holes for correspondingly engaging with the guide tabs and the holding tabs, respectively.

In an embodiment of the present invention, the guide tabs are T-shaped and radially inward extended into the through hole; and the holding tabs are axially bent toward an inner side of the frame.

With these arrangements, the cover and the frame of the shielding case are removably connected to each other via the slide engagement of the slide channels with the guide rails and the releasable engagement of the retaining holes with the limiting sections, so that the shielding case can be easily assembled and disassembled according to actual need.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is an exploded perspective view of a conventional shielding case for a communication device;

FIG. 2 is an exploded perspective view of a shielding case according to a preferred embodiment of the present invention;

FIG. 3 is an assembled view of FIG. 2;

FIG. 4 is a front view of FIG. 3;

FIG. 5 is an enlarged view of the circled area A of FIG. 4;

FIG. 6 is a top view showing the connection of a connector to a frame of the shielding case according to the preferred embodiment of the present invention;

FIG. 7 is a sectional view taken along line A-A′ of FIG. 6; and

FIG. 8 is a sectional view taken along line B-B′ of FIG. 6.

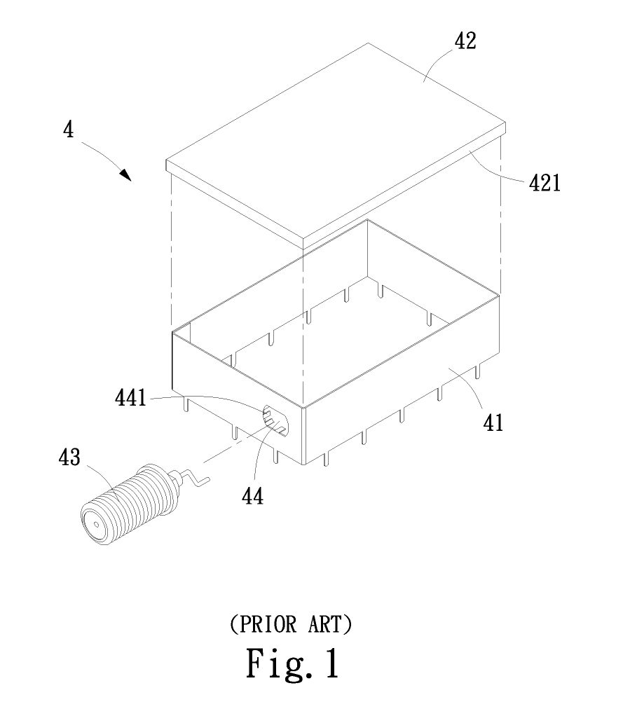

### DETAILED DESCRIPTION OF THE PREFERRED EMBODIMENTS

The present invention will now be described with a preferred embodiment thereof and with reference to the accompanying drawings.

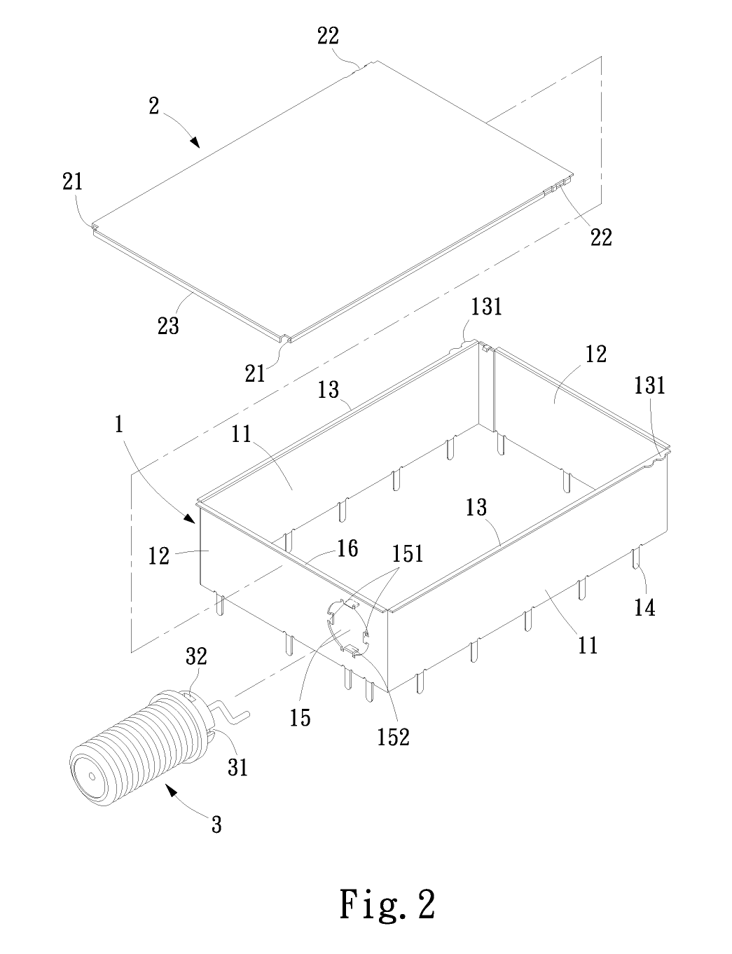

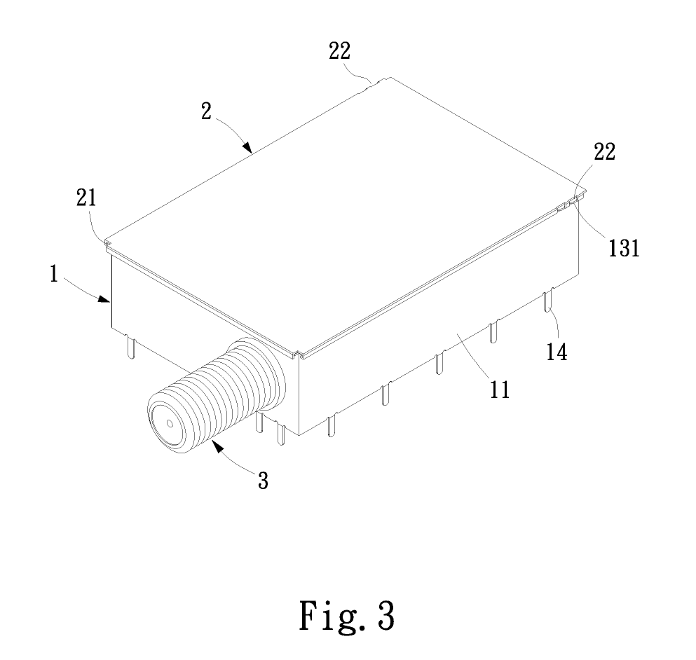

Please refer to FIGS. 2 and 3 that are exploded and assembled perspective views, respectively, of a shielding case according to a preferred embodiment of the present invention. As shown, the shielding case in the preferred embodiment of the present invention includes a frame 1, a cover 2, and a connector 3.

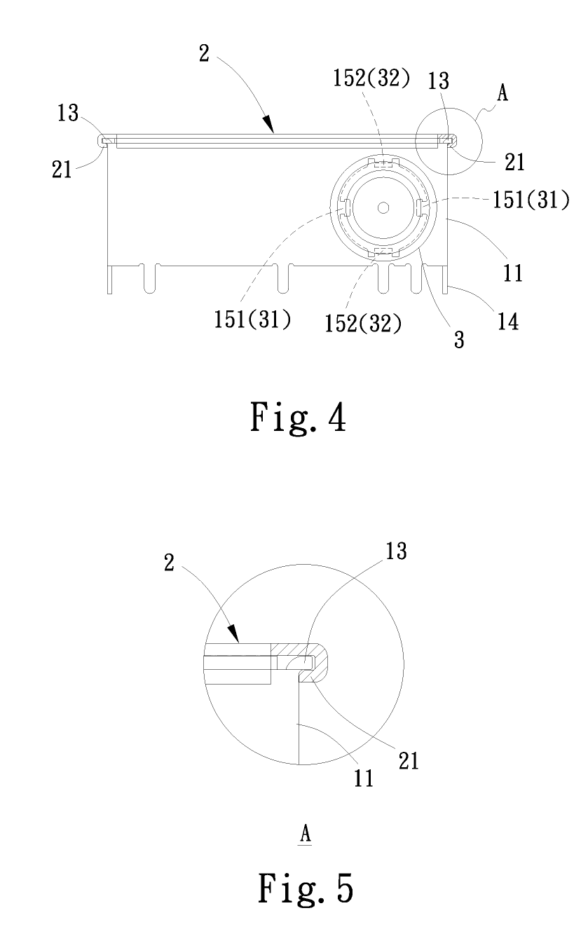

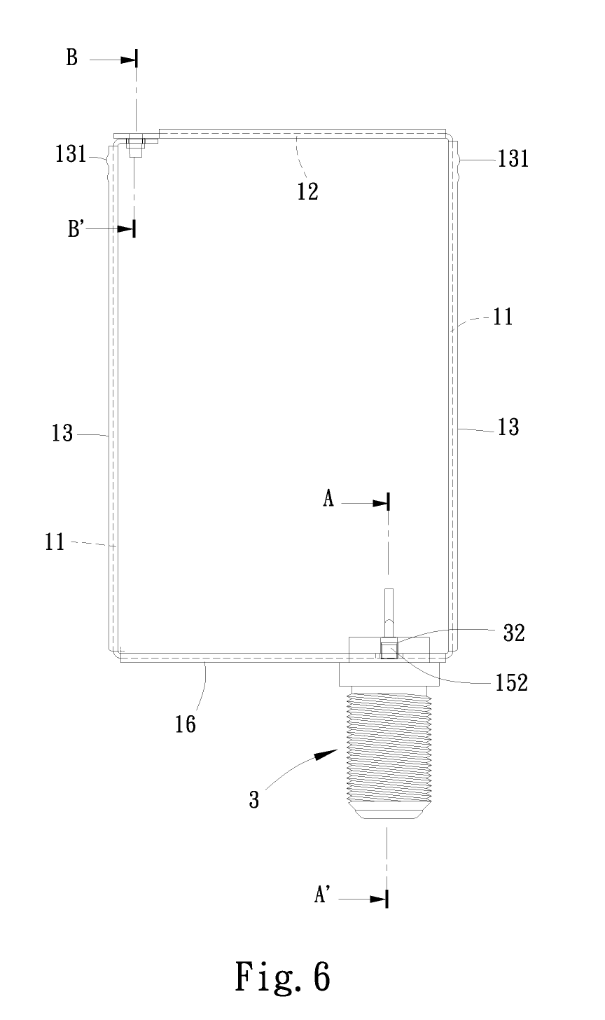

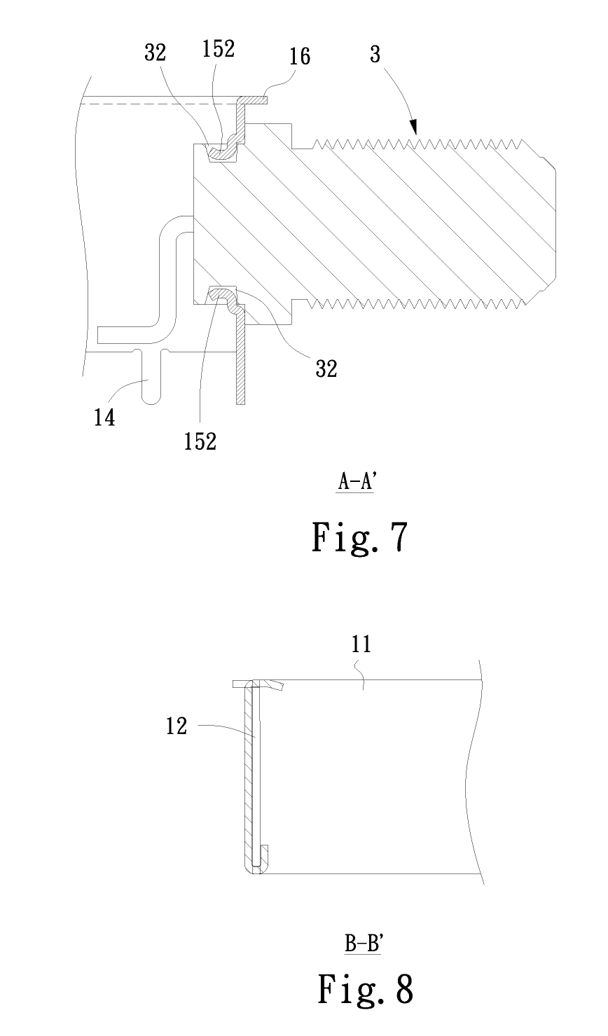

The frame 1 includes two opposite side walls 11 and two opposite end walls 12, which are connected to one another to define an open top of the frame 1. Please also refer to FIG. 4 that is a front view of FIG. 3 and to FIG. 5 that is an enlarged view of the circled area A of FIG. 4. The two side walls 11 are provided on respective top edge with a guide rail 13. The guide rails 13 are provided at respective one end with a limiting section 131, which includes continuous curved portions. A plurality of pins 14 is spaced along bottom edges of the frame 1. Please also refer to FIG. 6 that is a top view of the shielding case of the present invention, and to FIGS. 7 and 8 that are enlarged sectional views taken along lines A-A′ and B-B′ of FIG. 6, respectively. One of the two opposite end walls 12 of the frame 1 is provided with a through hole 15. A plurality of guide tabs 151 and a plurality of holding tabs 152 are internally spaced around the through hole 15. The guide tabs 151 are T-shaped and radially inward extended into the through hole 15. The holding tabs 152 are axially bent toward an inner side of the frame 1. And, the end wall 12 with the through hole 15 is also provided along a top edge with a stop flange 16.

The cover 2 is provided at two opposite lateral sides with slide channels 21 for correspondingly slidably receiving the guide rails 13 therein. The two slide channels 21 are provided at respective one end with a retaining hole 22 for correspondingly releasably engaging with the limiting sections 131. With these arrangements, the cover 2 is removably connected to top edges of the frame 1. Further, the cover 2 is provided along one of two opposite ends with a downward bent flange 23 for correspondingly bearing on the stop flange 16.

The connector 3 is mounted into the through hole 15 from an outer side of the frame 1. A plurality of recesses 31 and a plurality of mounting holes 32 are provided on an outer face of the connector 3 for correspondingly engaging with the guide tabs 151 and the holding tabs 152, respectively.

To assemble the shielding case of the present invention, first align the connector 3 with the through hole 15 on the frame 1 and slide the recesses 31 of the connector 3 onto the guide tabs 151 in the through hole 15. In this manner, the connector 3 can be fitted in the through hole 15 of the frame 1 at a predetermined angular position relative to the through hole 15 for the mounting holes 32 on the connector 3 to correspondingly align with the holding tabs 152 in the through hole 15. Then, bend the holding tabs 152 into the mounting holes 32 to complete the assembling of the connector 3 to the frame 1. Thereafter, connect the cover 2 to the frame 1 by correspondingly sliding the two slide channels 21 onto the two guide rails 13 of the frame 1. When the cover 2 is slid all the way to close the open top of the frame 1, the retaining holes 22 are brought to correspondingly releasably engage with the limiting sections 131, and the downward flange 23 is brought to bear on the stop flange 16. At this point, a shielding case for a communication device is completed.

To disassemble the shielding case, simply push the cover 2 in a reverse direction to disengage the retaining holes 22 from the limiting sections 131, and further slide the slide channels 21 of the cover 2 out of the guide rails 13 of the frame 1. Then, turn the holding tabs 152 out of the mounting holes 32 and move the connector 3 out of the through hole 15 under guiding of the guide tabs 151 that are still engaged with the recesses 31. In this manner, the cover 2 and the connector 3 can be easily separated from the frame 1.

With the above arrangements, the shielding case according to the present invention is novel, improved and industrially valuable. The present invention is novel and improved because the cover and the frame of the shielding case are removably connected to each other via the slide engagement of slide channels with guide rails and the releasable engagement of the retaining holes with the limiting sections, enabling the shielding case to be easily assembled and disassembled according to actual need. And, the present invention is industrially valuable because products derived from the present invention would no doubt fulfill the current market demands.

The present invention has been described with a preferred embodiment thereof and it is understood that many changes and modifications in the described embodiment can be carried out without departing from the scope and the spirit of the invention that is intended to be limited only by the appended claims.

What is claimed is:

1. A shielding case, comprising:
a frame defining an open top and being provided on two opposite lateral edges of the open top with a guide rail each, the guide rails being provided at respective one end with a limiting section; and the frame also being provided on bottom edges with a plurality of spaced pins, and at one of two opposite end faces with a through hole;
a cover being provided at two opposite lateral sides with a slide channel each for correspondingly slidably receiving the guide rails of the frame therein, the two slide channels being provided at respective one end with a retaining hole for correspondingly releasably engaging with the limiting sections on the frame, so that the cover is removably connected to the open top of the frame; and
a connector being detachably mounted to the through hole from an outer side of the frame.

2. The shielding case as claimed in claim 1, wherein the frame includes two opposite side walls and two opposite end walls, which are connected to one another; the slide channels being extended along top edges of the two side walls, and the through hole being provided on one of the two end walls; the end wall with the through hole also being provided on a top edge with a stop flange, and the cover being provided on one end with a downward bent flange for correspondingly bearing on the stop flange of the frame.

3. The shielding case as claimed in claim 1, wherein the limiting sections respectively include continuous curved portions.

4. The shielding case as claimed in claim 1, wherein the frame further includes a plurality of guide tabs and a plurality of holding tabs being internally spaced around the through hole; and the connector is provided on an outer surface with a plurality of recesses and a plurality of mounting holes for correspondingly engaging with the guide tabs and the holding tabs, respectively.

5. The shielding case as claimed in claim 4, wherein the guide tabs are T-shaped and radially inward extended into the through hole; and the holding tabs are axially bent toward an inner side of the frame.
